(19) United States
(12) Patent Application Publication
(10) Pub. No.: US 2012/0184111 A1
(43) Pub. Date: Jul. 19, 2012

(54) SELECTIVE PLASMA NITRIDING METHOD AND PLASMA NITRIDING APPARATUS

(75) Inventors: Taichi Monden, Nirasaki-shi (JP); Hideo Nakamura, Nirasaki-shi (JP); Junichi Kitagawa, Nirasaki-shi (JP)

(73) Assignee: TOKYO ELECTRON LIMITED, Tokyo (JP)

(21) Appl. No.: 13/499,055

(22) PCT Filed: Sep. 29, 2010
(86) PCT No.: PCT/JP2010/066933

§ 371 Date: Mar. 29, 2012

(30) Foreign Application Priority Data
Sep. 30, 2009 (JP) 2009-227637

(51) Int. Cl. H01L 21/318; C23C 16/50

(52) U.S. Cl. 438/776; 118/696; 257/E21.293

(57) ABSTRACT

A selective plasma nitriding method includes mounting an object to be processed on a mounting table in a processing chamber of a plasma processing apparatus, the object having a silicon surface and a silicon compound layer exposed; setting a pressure in the processing chamber within the range of about 66.7 Pa to 667 Pa; and generating a nitrogen-containing plasma while applying a bias voltage to the object by supplying to the mounting table a high frequency power with an output of about 0.1 W/cm² to 1.2 W/cm² per unit area of the object. The plasma nitriding method further includes selectively nitriding the silicon surface by the nitrogen-containing plasma to form a silicon nitride film.

### FIELD OF THE INVENTION

The present invention relates to a selective plasma nitriding method and a plasma nitriding apparatus.

### BACKGROUND OF THE INVENTION

In a semiconductor device manufacturing process, a silicon nitride film is formed by nitriding silicon by using a plasma. Generally, a silicon compound layer formed by a previous process remains, in addition to a silicon surface as an object of a plasma nitriding process, on a substrate. When the plasma nitriding process is performed in a state where various types of films exist, the entire exposure surface is exposed to the plasma. Accordingly, a nitrogen-containing layer is formed at regions where nitriding is not required. For example, when silicon is nitrided, a silicon oxide film (SiO₂ film) formed on the substrate is nitrided together with the silicon. As a consequence, the silicon oxide film may be modified to a silicon oxynitride film (SiON film).

However, when a film made of other than silicon as a target to be nitrided is nitrided during the semiconductor device manufacturing process, undesirable effects such as increase in the number of processes, decrease in a product yield or the like may be caused. This is because when such film is removed by, e.g., etching, in a post process, the etching selectivity to other films is changed.

In a flash memory, an insulating film is formed by nitriding an upper portion and a lower portion to form an ONO (Oxide-Nitride-Oxide) structure for covering a surface of a floating gate electrode therebetween. In this case, if a plasma nitriding process is performed after the floating gate electrode made of polysilicon is formed on a silicon substrate, a surface of an isolation film for separating adjacent cells is also nitrided, thereby forming a silicon oxynitride film. Accordingly, an unnecessary nitrogen-containing layer (SiON layer) remains in the isolation film of the finally fabricated flash memory. The remaining unnecessary nitrogen-containing layer may cause electrical interference between adjacent cells and deteriorate the data retention performance of the flash memory.

International Publication WO2007/034871 suggests a selective plasma nitriding method in which silicon of an object to be processed having the silicon and a silicon oxide film exposed is nitrided with a high selectivity to the silicon oxide film by using a plasma. In this method, the selective nitriding process is carried out by utilizing a binding energy difference between materials of the films. In other words, the silicon having a relatively low bonding energy is nitrided while suppressing nitriding of the silicon oxide film having a relatively high binding energy, so that the plasma nitriding process is performed by generating nitrogen ions having an energy level that is intermediate between the binding energy levels of the two materials. Further, in this method, the ion energy of the nitrogen ions in the plasma is controlled by setting the process pressure to be within a range from about 400 Pa to about 1000 Pa.

In the method suggested in International Publication WO2007/034871 in which the ion energy of the plasma is controlled by using a relatively high process pressure, high selectivity is obtained, whereas a nitriding power to silicon as an object to be nitrided is decreased. Therefore, a high nitriding rate or a high nitrogen concentration (nitrogen dose amount) is not obtained. Moreover, as the pressure of the plasma process is increased, the plasma distribution becomes non-uniform, which makes it difficult to obtain uniformity of the nitriding process in the surface of the substrate.

### SUMMARY OF THE INVENTION

In view of the above, the present invention provides a method for selectively nitriding silicon at a high nitriding rate and a high nitrogen dose amount on an object to be processed in which the object has a silicon surface and a silicon compound layer exposed.

Further, the present invention provides a plasma nitriding apparatus for performing the above method.

In accordance with one aspect of the present invention, there is provided a selective plasma nitriding method including: mounting an object to be processed on a mounting table in a processing chamber of a plasma processing apparatus, the object having a silicon surface and a silicon compound layer exposed; setting a pressure in the processing chamber within the range of about 66.7 Pa to 667 Pa; generating a nitrogen-containing plasma while applying a bias voltage to the object by supplying to the mounting table a high frequency power with an output of about 0.1 W/cm² to 1.2 W/cm² per unit area of the object; and selectively nitriding the silicon surface by the nitrogen-containing plasma to form a silicon nitride film.

The silicon compound layer may be a silicon oxide film. Further, a nitriding selectivity of the silicon to the silicon oxide film may be greater than or equal to 2

Preferably, the pressure in the processing chamber may be set to be in the range of about 133 Pa to 400 Pa.

Further, a frequency of the high frequency power may be in the range of about 400 kHz to 60 MHz.

Preferably, a processing time may be in the range of about 10 seconds to 180 seconds.

Further, a processing time may be in the range of about 10 seconds to 90 seconds.

Preferably, the nitrogen-containing plasma may be a microwave excitation plasma generated by a processing gas and a microwave introduced into the processing chamber by a planar antenna having a plurality of slots.

Further, a power density of the microwave per unit area of the object may be in the range of about 0.255 W/cm² to 2.55 W/cm².

Preferably, a process temperature may be in the range of a room temperature to about 600° C.

In accordance with another aspect of the present invention, there is provided a plasma nitriding apparatus including: a processing chamber for processing, by using a plasma, an object having a silicon surface and a silicon compound layer exposed; a gas exhaust unit for depressurizing and exhausting the interior of the processing chamber; a plasma generation unit for generating a plasma in the processing chamber; a mounting table for mounting thereon the object in the processing chamber; a high frequency power supply connected to the mounting table; and a control unit programmed to control a selective plasma processing method to be performed. The selective plasma processing method includes setting a pressure in the processing chamber within the range of about 66.7 Pa to 668 Pa; generating a nitrogen-containing plasma while applying a bias voltage to the object to be processed by supplying to the mounting table a high frequency power with an output of about 0.1 W/cm² to 1.2 W/cm² per unit area of the object; and selectively nitriding the silicon surface by the nitrogen-containing plasma to form a silicon nitride film.

In accordance with the selective plasma nitriding method of the present invention, the plasma nitriding process is performed while applying a bias voltage to the object to be processed, the object having the silicon surface and the silicon compound layer (e.g., SiO₂ film), so that the silicon can be nitrided with high selectivity. In other words, even when the silicon compound layer exist on the object to be processed, in addition to the silicon to be nitrided, it is possible to nitride the silicon predominantly. Accordingly, by applying the method of the present invention to the semiconductor device manufacturing process, a highly reliable semiconductor device can be manufactured without forming a nitrogen-containing layer on an undesired region and while preventing adverse effect caused by the nitrogen-containing layer, e.g., electrical interference between adjacent cells and the like.

### BRIEF DESCRIPTION OF THE DRAWINGS

FIG. 1 explains an object to be subjected to a selective plasma nitriding method of the present invention.

FIG. 2 is a flowchart of a selective plasma nitriding process.

FIG. 3 explains the object that has been subjected to the selective plasma nitriding process.

FIG. 4 is a schematic cross sectional view showing a configuration example of a plasma nitriding apparatus suitable for implementing the selective plasma nitriding method of the present invention.

FIG. 5 shows a structure of a planar antenna.

FIG. 6 is an explanatory view showing a configuration of a control unit.

FIG. 7 is a graph showing relationship between a Si/SiO₂ selectivity and a nitrogen dose amount to silicon.

FIG. 8 is a graph showing pressure dependence of the Si/SiO₂ selectivity.

FIG. 9 is a graph showing pressure dependence of the nitrogen dose amount to silicon.

FIG. 10 is a graph showing bias power dependence of the Si/SiO₂ selectivity.

FIG. 11 is a graph showing bias power dependence of the nitrogen dose amount to silicon.

FIG. 12 is a graph showing processing time dependence of the Si/SiO₂ selectivity.

FIG. 13 is a graph showing processing time dependence of the nitrogen dose amount to silicon.

FIG. 14 is a graph showing relationship between an increased film amount and a nitrogen dose amount in the case of performing an oxidation process on a silicon nitride film.

FIG. 15 is a graph showing measurement results of in-plane thickness uniformity of a silicon nitride film which are obtained when a bias is applied and when a bias is not applied.

FIG. 16 is a graph showing relationship between a nitrogen dose amount and Vdc in the case of performing a plasma nitriding process on a Si surface and a SiO₂ surface.

FIG. 17 is a cross sectional view showing a structure of a flash memory that can be fabricated by applying the selective plasma nitriding method of the present invention.

FIG. 18 explains a state before the selective plasma nitriding process during fabrication of a flash memory.

FIG. 19 explains a state after the selective plasma nitriding process during fabrication of a flash memory.

FIG. 20 explains an electron leakage mechanism of a conventional flash memory.

### DETAILED DESCRIPTION OF THE EMBODIMENTS

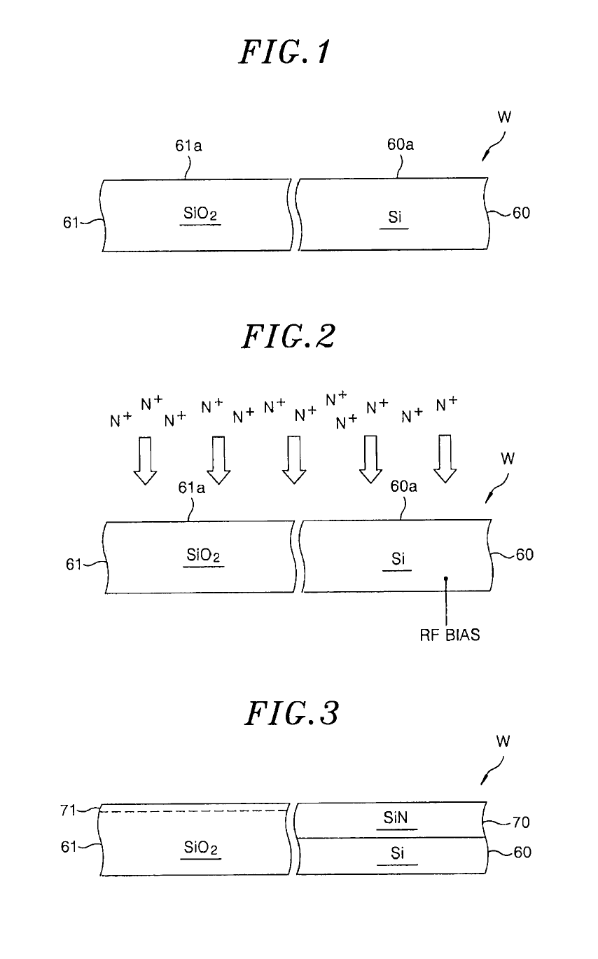

Hereinafter, the embodiment of the selective plasma nitriding method of the present invention will be described in detail with reference to the accompanying drawings. First, an outline of the selective plasma nitriding method of the present embodiment will be described with reference to FIGS. 1 to 3. FIG. 1 shows a cross section of a semiconductor wafer (hereinafter, referred to as a “wafer”) as an object to be subjected to the selective plasma nitriding process of the present invention. A silicon layer and a SiO₂ layer 61 as a silicon compound layer are exposed on the wafer W. Further, the silicon layer 60 may be single crystalline silicon, polycrystalline silicon or the like.

By exposing the wafer W to the nitrogen-containing plasma, the plasma nitriding process is performed on the Si surface 60a of the silicon layer 60 by active species in the nitrogen-containing plasma (mainly, N ions). At this time, the SiO₂ surface 61a of the SiO₂ layer 61 as well as the Si surface 60a of the silicon layer 60 are exposed on the wafer W. Therefore, the SiO₂ surface 61a of the SiO₂ layer 61 is also exposed to N ions in the plasma. In order to predominantly nitride the Si surface 60a while minimizing nitriding of the SiO₂ surface 61a, it is required to increase a nitriding selectivity of the Si surface 60a to the SiO₂ surface 61a (simply, referred to as a ‘Si/SiO₂ selectivity’).

In the selective plasma nitriding process of the present invention, the Si surface 60a of the silicon layer 60 is selectively nitrided while suppressing nitriding of the SiO₂ surface 61a of the SiO₂ layer 61 by utilizing the binding energy difference between the Si—Si bonding of the silicon layer 60 and the Si—O bonding of the SiO₂ layer 61. The binding energy of the Si—Si bonding is about 2.3[eV], and the binding energy of the Si—O bonding is about 4.6[eV]. By controlling the process pressure such that the ion energy E of the N ions is greater than about 2.3[eV] and smaller than about 4.6[eV], the plasma nitriding process for nitriding the Si surface 60a can be predominantly performed without nitriding the surface of the SiO₂ surface 61a.

The ion energy E of the N ions in the plasma is changed in accordance with the process pressure. The ion energy E tends to be decreased as the process pressure is increased within the range that can be set in the plasma nitriding process (about 1 Pa to 1333 Pa). Further, the pressure range of about 1 Pa to 1333 Pa is set to a ‘settable pressure range’ in the plasma nitriding process, and ‘high pressure’ and ‘low pressure’ imply relative levels of a pressure within the settable pressure range.

The selectivity is improved by controlling the process pressure. However, as the pressure is increased, N radicals act predominantly as active species in the plasma, so that the nitriding power tends to be decreased. Therefore, it is difficult and practically insufficient to increase a nitriding rate and a nitrogen dose amount with respect to the Si surface 60a of the silicon layer 60 only by setting a process pressure to a high level. Accordingly, in the selective plasma nitriding process of the present invention, a high frequency bias voltage (hereinafter, simply referred to as a ‘bias’) is applied to the wafer W, as illustrated in FIG. 2. As a consequence, the decrease of the nitriding power under high pressure conditions is compensated, and a larger number of N ions are attracted to the wafer W compared to when the bias is not applied. By combining the control of the process pressure and the application of the bias, the plasma nitriding process can be performed at a high nitriding rate and a high nitrogen dose amount while ensuring a high selectivity.

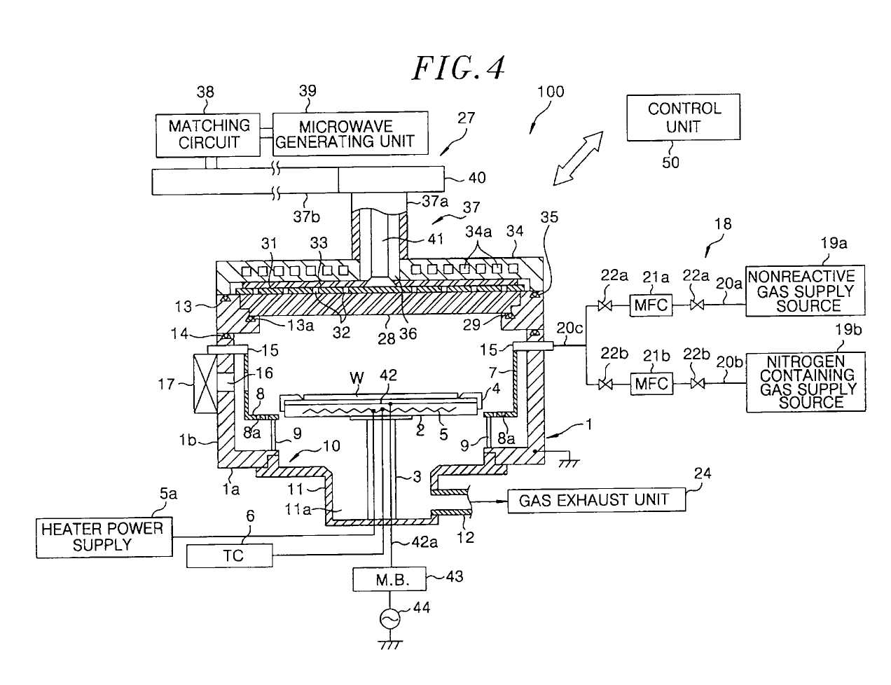

As a result, the silicon layer 60 of the wafer W is selectively nitrided, and a silicon nitride film 70 is formed as shown in FIG. 3. Further, the SiO₂ surface 61a of the SiO₂ layer 61 is slightly nitrided, and a nitrogen-containing layer (SiON layer) 71 is formed. Since, however, the nitrogen-containing layer 71 has a thickness smaller than that of the silicon nitride film 70 formed on the Si surface 60a, the nitrogen-containing layer 71 can be easily removed by etching or the like by utilizing the film thickness difference without affecting the semiconductor devices. In view of this, in the selective plasma nitriding process of the present invention, the Si/SiO₂ is preferably set to be greater than or equal to 2, and more preferably set to be greater than or equal to 4.

In addition, in the selective nitriding process of the present invention, the nitrogen dose amount introduced into the silicon is preferably set to be greater than or equal to about 10×10¹⁵ atoms/cm², and more preferably set to be greater than or equal to about 17×10¹⁵ atoms/cm². By setting the nitrogen dose amount to be greater than or equal to about 10×10¹⁵ atoms/cm², when an oxidation process is carried out after the selective plasma nitriding process during the semiconductor device manufacturing process, a barrier function is obtained to suppress an increase of the silicon oxynitride film.

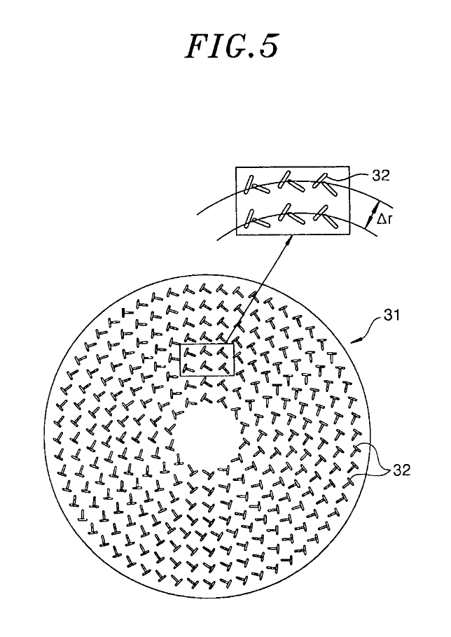

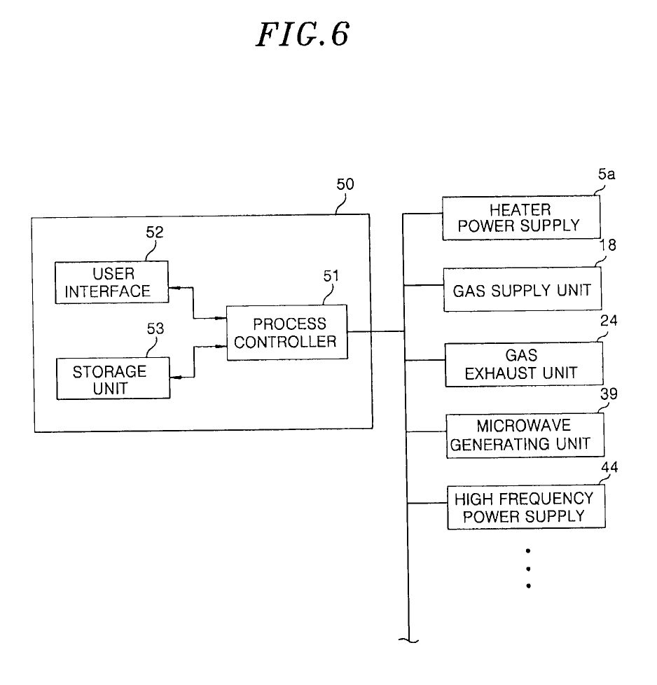

Hereinafter, the configuration of the plasma nitriding apparatus that can be used for the selective plasma nitriding method of the present invention and the sequence of the selective plasma nitriding process will be described with reference to FIGS. 4 to 6. FIG. 4 is a cross sectional view schematically showing a configuration of the plasma nitriding apparatus 100. FIG. 5 is a top view showing a planar antenna of the plasma nitriding apparatus 100. FIG. 6 explains a configuration of a control system of the plasma nitriding apparatus 100.

The plasma nitriding apparatus 100 is configured as an RLSA (radial line slot antenna) microwave plasma processing apparatus capable of generating a microwave excitation plasma of a high density and a low electron temperature in a processing chamber by directly introducing a microwave into the processing chamber by using a planar antenna having a plurality of slots, particularly an RLSA. Therefore, the plasma nitriding apparatus 100 can perform a process using a plasma having a density of about 1×10¹⁰ to 5×10¹²/cm³ and a low electron temperature of about 0.7 to 2 eV. Accordingly, the plasma nitriding apparatus 100 can be preferably used to form a silicon nitride film (SiN film) in a manufacturing process of various semiconductor devices.

The plasma nitriding processing apparatus 100 mainly includes: a processing chamber 1 accommodating a wafer W as an object to be processed; a mounting table 2 for mounting thereon the wafer W in the processing chamber 1; a gas supply unit 18 for supplying a gas into the processing chamber 1; a gas inlet 15 connected to the gas supply unit 18; a gas exhaust unit 24 for depressurizing and exhausting the interior of the processing chamber 1; a microwave introducing unit 27 provided at an upper portion of the processing chamber 1 and serving as a plasma generation unit for generating a plasma by introducing a microwave into the processing chamber 1; and a control unit 50 for controlling each component of the plasma nitriding apparatus 100. The gas supply unit 18 may not be included in the components of the plasma nitriding apparatus 100. In that case, an external gas supply unit may be connected to the gas inlet 15.

The processing chamber 1 is formed by a substantially cylindrical container which is grounded. Further, the processing chamber 1 may be formed by a square column shaped container. The processing chamber 1 has an open top end, and has a bottom wall 1a and a sidewall 1b made of aluminum or the like.

The mounting table 2 for horizontally supporting a wafer W as an object to be processed is provided in the processing chamber 1. The mounting table 2 is made of ceramic such as AlN, Al₂O₃ or the like. Preferably, the mounting table 2 is made of a material having high thermal conductivity, e.g., AlN. The mounting table 2 is supported by a cylindrical support member 3 extending upwardly from a center of a bottom portion of the gas exhaust chamber 11. The support member 3 is made of, e.g., ceramic such as AlN or the like.

Further, the mounting table 2 has a covering member 4 covering outer peripheral portion or entire surface thereof for guiding the wafer W. The covering member 4 is formed in an annular shape and covers the mounting surface and/or the side surface of the mounting table 2. By inhibiting the mounting table 2 from being exposed to the plasma by the covering member 4, thus preventing the mounting table 2 from being sputtered, intrusion of impurities into the wafer W can be prevented. The covering member 4 is made of a material, e.g., quartz, single crystalline silicon, polycrystalline silicon, amorphous silicon, SiN or the like. Among them, it is most preferably made of quartz compatible with a plasma. Further, the covering member 4 is preferably made of a high-purity material with a low content of impurities, such as an alkali metal, a metal or the like.

In addition, a resistance heater 5 is buried in the mounting table 2. The heater 5 heats the mounting table 2 by using electric power supplied from a heater power supply 5a, so that the wafer W as an object to be processed is uniformly heated by the heat.

The mounting table 2 is provided with a thermocouple (TC) 6. By measuring the temperature by the thermocouple 6, a heating temperature of the wafer W can be controlled between a room temperature and about 900° C.

Further, wafer support pins (not shown) used for transferring the wafer W in the case of loading the wafer W into the processing chamber 1 are provided at the mounting table 2. Each of the wafer support pins can be protruded from and retracted into the surface of the mounting table 2.

Besides, a bias application unit for applying a bias to the wafer W is provided at the mounting table 2. The bias application unit will be described later.

A cylindrical liner 7 made of quartz is provided at an inner peripheral portion of the processing chamber 1. Further, an annular baffle plate 8 made of quartz and having a plurality of gas exhaust holes 8a is provided at an outer peripherally portion of the mounting table 2 in order to uniformly exhaust the processing chamber 1. The baffle plate 8 is supported by a plurality of columns 9.

A circular opening 10 is formed at a substantially central portion of the bottom wall 1a in the chamber 1. A gas exhaust chamber 11 extends downward from the bottom wall 1a and communicates with the opening 10. The gas exhaust chamber 11 is connected to a gas exhaust line 12, and the gas exhaust line 12 is connected to a gas exhaust unit 24. Accordingly, the processing chamber 1 can be exhausted to vacuum.

A plate 13 having an opening is provided at an upper portion of the processing chamber 1. An inner peripheral portion of the plate 13 protrudes inwardly (toward the inner space of the processing chamber) and thus forms an annular support portion 13a. The space between the plate 13 and the processing chamber 1 is airtightly sealed by a sealing member 14.

Provided on the sidewall 1b of the processing chamber 1 are a loading/unloading port 16 for loading and unloading the wafer W between the plasma nitriding apparatus 100 and a transfer chamber (not shown) adjacent thereto, and a gate valve 17 for opening and closing the loading/unloading port 16.

An annular gas inlet 15 is disposed at the sidewall 1b of the processing chamber 1. The gas inlet 15 is connected to a gas supply unit 18 for supplying a nitrogen-containing gas or a gas for plasma excitation. Further, the gas inlet 15 may be formed in a nozzle shape or a gas shower shape.

The gas supply unit 18 includes a gas supply source (e.g., a nonreactive gas supply source 19a and a nitrogen-containing gas 19b), lines (e.g., gas lines 20a, 20b and 20c), a flow rate controller (e.g., mass flow controllers 21a and 21b) and valves (e.g., opening/closing valves 22a and 22b). Further, the gas supply unit 18 may have, other than the above-described gas supply sources (not shown), a purge gas supply source used to replace the atmosphere in the processing chamber 1 or the like.

As for the nonreactive gas, it is possible to use, e.g., a rare gas or the like. As for the rare gas, it is possible to use, e.g. Ar gas, Kr gas, Xe gas, He gas or the like. Among them, it is especially preferable to use Ar gas in view of economical efficiency. The nitrogen-containing gas is a gas containing nitrogen atoms, e.g., nitrogen gas (N₂), ammonia gas (NH₃), NO, N₂O or the like.

The nonreactive gas and the nitrogen-containing gas are supplied from the nonreactive gas supply source 19a and the nitrogen-containing gas supply source 19b via the gas lines 20a and 20b, respectively, and are mixed in the gas line 20c. The mixed gas flows to the gas inlet 15 connected to the gas line 20c, and then is introduced into the processing chamber 1 through the gas inlet 15. Each of the gas lines 20a and 20b connected to the gas supply sources is respectively provided with mass flow controllers 21a and 21b and a pair of opening/closing valves 22a and 22b disposed at an upstream and a downstream of the mass flow controllers 21a and 21b. With this configuration of the gas supply unit 18, it is possible to switch the supplied gas or control a flow rate thereof.

The gas exhaust unit 24 includes a high speed vacuum pump, e.g., a turbo molecular pump or the like. As described above, the gas exhaust unit 24 is connected to the gas exhaust chamber 11 of the processing chamber 1 via the gas exhaust line 12. By operating the gas exhaust unit 24, the gas in the processing chamber 1 uniformly flows in the space 11a of the gas exhaust chamber 11, and is discharged from the space 11a to the outside via the gas exhaust line 12. Accordingly, the interior of the processing chamber 1 can be depressurized to, e.g., about 0.133 Pa, at a high speed.

Hereinafter, the configuration of the microwave introducing unit 27 will be described. The microwave introducing unit 27 mainly includes a transmitting plate 28, a planar antenna 31, a wave retardation member 33, a covering member 34, a waveguide 37, and a matching circuit 38, and a microwave generating unit 39. The microwave introducing unit 27 serves as a plasma generation unit for generating a plasma by introducing an electromagnetic wave (microwave) into the processing chamber 1.

The transmitting plate 28 is provided on the support portion 13a protruded from the plate 13 toward its inner peripheral portion. The microwave transmitting plate 28 is made of a dielectric material, e.g., quartz or ceramic such as Al₂O₃, AlN or the like. The transmitting plate 28 and the support portion 13a are airtightly sealed via a sealing member 29 such as an O-ring or the like. Therefore, the interior of the processing chamber 1 is airtightly maintained.

The planar antenna 31 is provided above the transmitting plate 28 (outside the processing chamber 1) so as to face the mounting table 2. The planar antenna 31 is formed in a disc shape. However, the planar antenna 31 is not limited to the disc shape but may be of, e.g., a quadrilateral plate shape. The planar antenna 31 is engaged to the top end of the plate 13.

The planar antenna 31 is made of a conductive member, e.g., a nickel plate, an aluminum plate or a copper plate whose surface is coated with gold or silver, or an alloy thereof. The planar antenna 31 has a plurality of slot-shaped microwave irradiation holes 32 for radiating a microwave. The microwave irradiation holes 32 are formed through the planar antenna 31 in a predetermined pattern.

As illustrated in FIG. 5, each of the microwave irradiation holes 32 has a thin and long rectangular shape (slot shape). Further, a pair of adjacent microwave irradiation holes 32 is typically arranged in a “L” shape. Furthermore, such pairs of the microwave irradiation holes arranged in a predetermined shape (e.g., L-shape) are arranged along concentric circular lines as a whole.

A length of each of the microwave irradiation holes 32 or an arrangement interval between the microwave irradiation holes 32 is determined by a wavelength (λg) of a microwave. For example, the microwave irradiation holes 32 are arranged so as to be spaced apart from each other at an interval of λg/4 to λg. Referring to FIG. 5, a distance between the adjacent microwave irradiation holes 32 arranged concentrically is indicated by Δr. Each of the microwave irradiation holes 32 may have a circular shape, an arc shape or the like. Further, the microwave irradiation holes 32 may be arranged in, e.g., a spiral shape, a radial shape or the like without being limited to the concentric pattern.

A wave retardation member 33 having a dielectric constant greater than that of vacuum is provided on a top surface of the planar antenna 31 (a planar waveguide formed between the planar antenna 31 and the covering member 34). Since the wavelength of microwaves is increased in a vacuum, the wave retardation member 33 serves to shorten the wavelength of microwaves to thereby control a plasma. The wave retardation member 33 may be made of, e.g., quartz, polytetrafluoroethylene resin, polyimide resin or the like.

Although there may exist a gap between the planar antenna 31 and the transmitting plate 28 and between the wave retardation member 33 and the planar antenna 31, it is preferable that there is no gap therebetween.

The covering member 34 is provided at an upper portion of the processing chamber 1 so as to cover the planar antenna 31 and the wave retardation member 33. The covering member 34 is made of, e.g., a metal material such as aluminum, stainless steel or the like. The planar waveguide is formed by the covering member 34 and the planar antenna 31, so that the microwave can be uniformly supplied into the processing chamber 1. The top surface of the plate 13 and the covering member 34 are sealed by a sealing member 35. Further, a cooling water path 34a is formed in the covering member 34. The covering member 34, the wave retardation member 33, the planar antenna 31, and the transmitting plate 28 can be cooled by circulating cooling water through the cooling water path 34a. In addition, the covering member 34 is grounded.

An opening 36 is formed at the center of the upper wall (ceiling portion) of the covering member 34, and a waveguide 37 is connected to the opening 36. The microwave generating unit 39 for generating a microwave is connected to the other end of the waveguide 37 via a matching circuit 38.

The waveguide 37 includes a coaxial waveguide 37a having a circular cross section and extending upward from the opening 36 of the covering member 34, and a horizontally-extending rectangular waveguide 37b connected to the upper end portion of the coaxial waveguide 37a via a mode transducer 40. The mode transducer 40 has a function of converting the microwave propagated through the rectangular waveguide 37b in a TE mode into a TEM mode.

An internal conductor 41 extends in the center of the coaxial waveguide 37a. The lower end portion of the internal conductor 41 is connected and fixed to the center of the planar antenna 31. This allows the microwave to be efficiently and uniformly propagated through the internal conductor 41 in the coaxial waveguide 37a to the planar waveguide formed by the planar antenna 31 radially.

With the above-described configuration of the microwave introducing unit 27, the microwave generated by the microwave generating unit 39 is propagated to the planar antenna 31 via the waveguide 37, and then is introduced from the microwave irradiation holes 32 (slots) into the processing chamber 1 via the transmitting plate 28. The microwave has preferably a frequency of, e.g., 2.45 GHz, and may also have a frequency of 8.35 GHz, 1.98 GHz, or the like.

Hereinafter, the bias application unit for applying a bias to the mounting table 2 will be described. An electrode 42 is buried in the surface of the mounting table 2. A high frequency power for bias application 44 is connected to the electrode 42 via a matching box MB 43 by a power feed line 42a. In other words, the bias can be applied to the wafer W by supplying a high frequency power to the electrode 42. The electrode 42, the power feed line 42a, the matching box (M.B.) 43, and the high frequency power supply 44 form the bias application unit of the plasma nitriding apparatus 100. The electrode 42 may be made of a conductive member, e.g., molybdenum, tungsten or the like. The electrode 42 is formed in, e.g., a mesh shape, a lattice shape, a spiral shape or the like.

Each component of the plasma nitriding apparatus 100 is connected to and controlled by a control unit 50. The control unit 50 is typically a computer. As shown in FIG. 6, the control unit 50 includes a process controller 51 having a CPU, a user interface 52 and a storage unit 53 connected to the process controller 51. The process controller 51 controls each component of the plasma nitriding apparatus 100 (e.g., the heater power supply 5a, the gas supply unit 18, the gas exhaust unit 24, the microwave generating unit 39, the high frequency power supply 44 and the like) which is related to the processing conditions such as a pressure, a temperature, a gas flow rate, a microwave output, a high frequency power for bias application and the like.

The user interface 52 has a keyboard on which a process operator inputs commands to operate the plasma nitriding apparatus 100, a display for visually displaying the operation status of the plasma nitriding apparatus 100 and the like. Further, the storage unit 53 stores therein recipes including control programs (software) for implementing various processes executed by the plasma nitriding apparatus 100 under the control of the process controller 51, processing condition data and the like.

Moreover, the process controller 51 executes a recipe retrieved from the storage unit 53 in response to an instruction from the user interface 52 or the like when necessary, so that a required process is performed by the plasma nitriding apparatus 100 under the control of the process controller 51. Further, recipes such as the control program, the processing condition data and the like may be stored in a computer-readable storage medium, e.g., a CD-ROM, a hard disk, a flexible disk, a flash memory, a DVD, a Blu-ray disc or the like, or may be transmitted on-line from another device via, e.g., a dedicated line, whenever necessary.

In the plasma nitriding apparatus 100 configured as described above, the plasma process can be carried out without inflicting damages on an underlying film or the substrate (wafer W) at a relatively low temperature not higher than about 600° C., e.g., between a room temperature (about 25° C.) and about 600° C. Further, the plasma nitriding apparatus 100 realizes excellent plasma uniformity and thus can uniformly process the wafer W (object to be processed) having a large diameter.

Hereinafter, the sequence of the selective plasma nitriding process performed by using the RLSA-type plasma nitriding process 100 will be described. First, the wafer W is loaded into the processing chamber 1 through the loading/unloading port 16 by opening the gate valve 17, and then is mounted on the mounting table 2. The wafer W has a silicon layer and a silicon compound layer (e.g., SiO₂ layer) whose surfaces are exposed (see FIG. 1). Then, an nonreactive gas and a nitrogen-containing gas are introduced at predetermined flow rates from the nonreactive gas supply source 19a and the nitrogen-containing gas supply source 19b of the gas supply unit 18 into the processing chamber 1 through the gas inlet 15, respectively, while exhausting and depressurizing the processing chamber 1. As a consequence, a pressure in the processing chamber 1 is adjusted to a predetermined level.

Next, the microwave of a predetermined frequency, e.g., 2.45 GHz, generated in the microwave generating unit 39 is transferred to the waveguide 37 via the matching circuit 38. The microwave transferred to the waveguide 37 sequentially passes through the rectangular waveguide 37b and the coaxial waveguide 37a, and then is supplied to the planar antenna 31 via the internal conductor 41. In other words, the microwave is propagated in the TE mode in the rectangular waveguide 37b, and is converted from the TE mode into the TEM mode by the mode transducer 40, and then is propagated in the TEM mode through the coaxial waveguide 37a to the planar antenna 31. Then, the microwave is radiated from the slot-shaped microwave irradiation holes 32 penetrating the planar antenna 31 to the space above the wafer W in the processing chamber 1 through the transmitting plate 28. At this time, the power density as an output of the microwave can be selected from the range of, e.g., about 0.255 W/cm² to 2.55 W/cm².

An electromagnetic field is formed in the processing chamber 1 by the microwave radiated from the planar antenna 31 into the processing chamber 1 through the transmitting plate 28, so that the processing gases such as the nonreactive gas and the nitrogen-containing gas are turned into a plasma. While the plasma nitriding process is being performed, a high frequency power of a predetermined frequency and a predetermined power level is supplied from the high frequency power supply 44 to the electrode 42 of the mounting table 2. Due to the high frequency power supplied from the high frequency power supply 44, a bias is applied to the wafer W, and the plasma nitriding process is accelerated while maintaining a low electron temperature (0.7 to 2 eV) of the plasma. In other words, the bias acts to attract nitrogen ions in the plasma toward the wafer W, and this increases the nitriding rate of the silicon.

By radiating the microwave through the plurality of microwave irradiation holes 32 of the planar antenna 31, the microwave excitation plasma used in the present invention has a high density of about 1×10¹⁰ to 5×10¹²/cm³ and a low electron temperature of about 1.2 eV or less at the vicinity of the wafer W. Under the low pressure condition (e.g., 20 Pa or less), a plasma mainly including ions is generated, and collision between particles is suppressed. Therefore, if the bias is applied to the substrate (wafer W) at a voltage of, e.g., about 100 to 200 V, the ions are accelerated, and the ion energy is increased. This may lead to damages of the substrate (wafer W). However, under the high pressure condition (e.g., about 66.7 Pa or above), a plasma mainly including radicals is generated and collision between particles is facilitated. Accordingly, the ion energy is decreased by the collision, and the substrate (wafer W) is hardly damaged even if the bias is applied thereto.

### <Plasma Nitriding Process Condition>

Hereinafter, desirable conditions of the selective plasma nitriding process performed by the plasma nitriding apparatus 100 will be described. In the selective plasma nitriding process of the present invention, (1) a process pressure, (2) a level of a bias applied to the wafer W and (3) processing time are important conditions. By balancing these conditions, it is possible to obtain a high Si/SiO₂ selectivity (a nitriding ratio of silicon to a silicon oxide film), a high nitriding rate, and a high dose amount.

### (Process Pressure)

In order to increase the Si/SiO₂ selectivity, the process pressure is preferably set to be in the range of about 66.7 Pa to 667 Pa, and more preferably set to be in the range of about 66.7 Pa to 133 Pa. When the process pressure is lower than about 66.7 Pa, a high nitriding rate is obtained, and Si and SiO₂ have substantially the same nitriding rate. Further, a sufficient Si/SiO₂ selectivity is not obtained. Meanwhile, when the process pressure is higher than about 667 Pa, the nitriding power is decreased, and it is difficult to obtain a sufficient nitriding rate and a sufficient nitrogen dose amount even if a bias is applied.

### (High Frequency Bias Voltage)

A frequency of a high frequency power supplied from the high frequency power supply 44 is preferably in the range of, e.g., about 400 kHz to 60 MHz, and more preferably in the range of about 400 kHz to 13.5 MHz. The high frequency power is preferably supplied at a power density per unit area of the wafer in the range of, e.g., about 0.1 W/cm² to 1.2 W/cm², and more preferably in the range of, e.g., about 0.4 W/cm² to 1.2 W/cm². When the power density is lower than about 0.1 W/cm², the attractive force of ions is weak, and a high nitriding rate and a high dose amount are not obtained. On the other hand, when the power density is higher than about 1.2 W/cm², a high nitriding rate is obtained; Si and SiO₂ have substantially the same nitriding rate; and the Si/SiO₂ selectivity is decreased. The high frequency power is preferably higher than or equal to about 100 W. For example, the high frequency power is preferably in the range of about 100 W to 1000 W, and more preferably in the range of about 300 W to 1000 W. The power density is set within the above-described range of the high frequency power.

By supplying the high frequency power to the electrode 42 of the mounting table 2, ions in the plasma are attracted to the wafer W while maintaining a low electron temperature of the plasma. Therefore, the plasma nitriding rate and the nitrogen dose amount can be improved by applying a bias to the wafer W by supplying the high frequency power to the electrode 42 of the mounting table 2. Further, in the plasma nitriding apparatus 100 used in the present embodiment, a plasma of a low electron temperature can be generated, and the application of a bias to the wafer W does not cause damage to the wafer W by ions or the like at a high pressure (e.g., 66.7 Pa or above). Moreover, a good-quality silicon nitride film can be formed at a low temperature in a short period of time while ensuring a high nitrogen dose amount and a high Si/SiO₂ selectivity.

### (Processing Time)

The processing time can be set in accordance with plasma processing conditions such as a thickness of a silicon nitride film 70 to be formed, a process pressure, a level of a bias or the like. However, the processing time is preferably set to be lower than or equal to about 180 seconds. For example, the processing time is preferably set in the range of about 10 second to 180 seconds, and more preferably set to be in the range of about 10 seconds to 90 seconds. As the processing time is increased, the nitrogen dose amount is increased in proportion to the processing time. However, the nitriding rate is saturated, thus the Si/SiO₂ selectivity is decreased. Therefore, in order to maintain the high Si/SiO₂ selectivity, it is preferable to minimize the processing time within the range in which a desired film thickness is obtained.

### (Processing Gas)

As for a processing gas, it is preferable to use Ar gas as a rare gas and N₂ gas as a nitrogen-containing gas. At this time, the flow rate ratio (volume ratio) of N₂ gas contained in the entire processing gases is not particularly limited. However, in order to achieve a high selectivity and increase a nitriding rate and a nitrogen dose amount, the flow rate ratio of N₂ gas is preferably in the range of about 10% to 70%, and more preferably in the range of about 17% to 60%. In the case of processing a wafer W having a diameter of, e.g., about 300 mm, the flow rate ratio can be set such that the flow rate of Ar gas is in the range of about 10 mL/min (sccm) to 2000 mL/min (sccm) and the flow rate of N₂ gas is in the range of about 1 mL/min (sccm) to 1400 mL/min (sccm).

### (Microwave Power)

In order to stably and uniformly generate a plasma and improve a nitrogen dose amount and a Si/SiO₂ selectivity, the power density of the microwave in the plasma nitriding process is preferably in the range of about 0.255 W/cm² to 2.55 W/cm². Further, the power density of the microwave in the present invention refers to a microwave power supplied per unit area of 1 cm² of the transmitting plate 28. Further, in the case of processing a wafer having a diameter of, e.g., about 300 mm or more, the microwave power is preferably set to be in the range of about 500 W to 5000 W, and more preferably set to be in the range of about 1000 W to 4000 W.

### (Process Temperature)

In order to further increase the nitrogen dose amount, the process temperature (the heating temperature of the wafer W) is preferably set to in the range of a room temperature (about 25° C.) to about 600° C. For example, the process temperature is preferably set to be in the range of about 200° C. to 500° C., and more preferably set to be in the range of about 400° C. to 500° C.

The above-described processing conditions can be stored as recipes in the storage unit 53 of the control unit 50. The process controller 51 retrieves the recipes and transmits control signals to the respective components of the plasma nitriding apparatus 100, e.g., the gas supply unit 18, the gas exhaust unit 24, the microwave generating unit 39, the heater power supply 5a, the high frequency power supply 44 and the like, thereby realizing a plasma nitriding process under desired conditions.

As described above, in the selective plasma nitriding method of the present embodiment, the nitriding rate and the nitrogen dose amount can be increased by attracting N ions in the plasma toward the wafer W by supplying the high frequency power to the electrode 42 of the mounting table 2. Further, by setting the process pressure to about 66.7 Pa or above, it is possible to increase the Si/SiO₂ selectivity of the nitriding process and predominantly nitride the silicon surface. Hence, the silicon nitride film having a desired film thickness can be formed by selectively nitriding the silicon. The silicon nitride film thus formed can serve as, e.g., an insulating film of a semiconductor memory device or the like.

Hereinafter, the test result on which the present invention is based will be described. The plasma nitriding process was performed on the Si surface and the SiO₂ surface by using the plasma nitriding apparatus 100 under the following conditions.

### <Conditions>

Process pressure: 20 Pa, 133 Pa, 400 Pa
Ar gas flow rate: 1800 mL/min(sccm)
N₂ gas flow rate: 360 mL/min(sccm)
Frequency of high frequency power: 13.56 MHz
Power of high frequency power: 0 W (no bias application), 450 W (power density: 0.5 W/cm²), 900 W (power density: 1.1 W/cm²)
Frequency of microwave: 2.45 GHz
Microwave power: 1500 W (power density: 2.1 W/cm²)
Process temperature: 500° C.
Processing time: 30 seconds, 90 seconds, 180 seconds
Wafer diameter: 300 mm

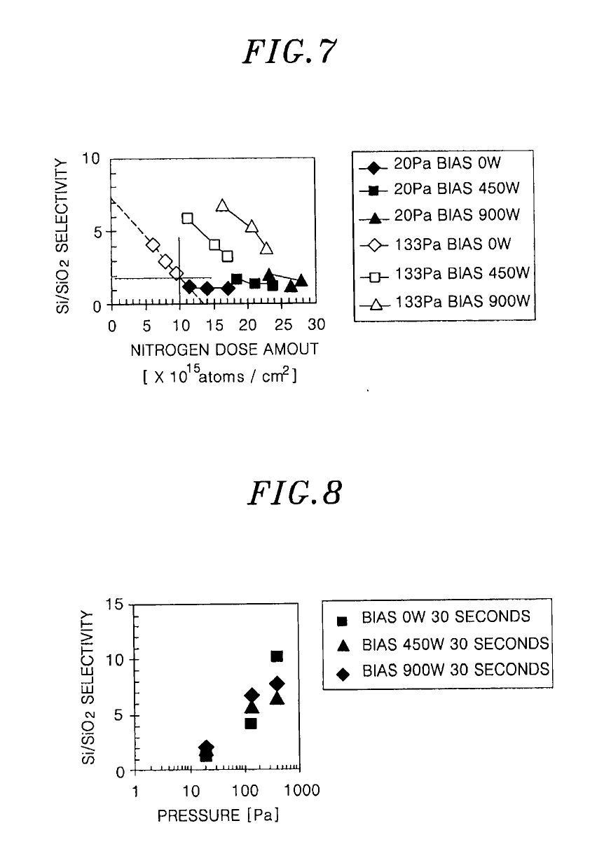

FIG. 7 is a graph plotting relationship between a Si/SiO₂ selectivity and a nitrogen dose amount to silicon in the case of setting a process pressure to about 20 Pa and 133 Pa. In the graph of FIG. 7, the vertical axis represents the Si/SiO₂ selectivity, and the horizontal axis represents the dose amount to silicon. Moreover, ┌Si/SiO₂ selectivity┘ is calculated based on the nitrogen dose amount. The connected plots in FIG. 7 show, from left to right, the processing time of about 30 seconds, 90 seconds and 180 seconds.

As shown in FIG. 7, under a low pressure condition of about 20 Pa, the Si/SiO₂ selectivity of about 1 was obtained when a bias was not applied, and the Si/SiO₂ selectivity of about 2 at maximum was obtained even when a bias was applied. Meanwhile, when the process pressure was set to about 133 Pa, the Si/SiO₂ selectivity was improved considerably. This is because when the pressure is increased, the ion energy is decreased, and the radicals act predominantly. However, the nitrogen dose amount (or nitriding rate) obtained at the pressure of about 133 Pa was lower than that obtained at the pressure of about 20 Pa. When a bias was not applied, the nitrogen dose amount smaller than about 10×10¹⁵ atoms/cm² was obtained even for the processing time of about 180 seconds. Meanwhile, when a bias was applied at a pressure of about 133 Pa, the plot was shifted toward a right upper portion in the graph in accordance with a level of the bias. From the above, it is clear that the ions are attracted to the wafer W by the bias application as well as the pressure control, so that the nitrogen dose amount (or nitriding rate) can be considerably improved while improving the Si/SiO₂ selectivity.

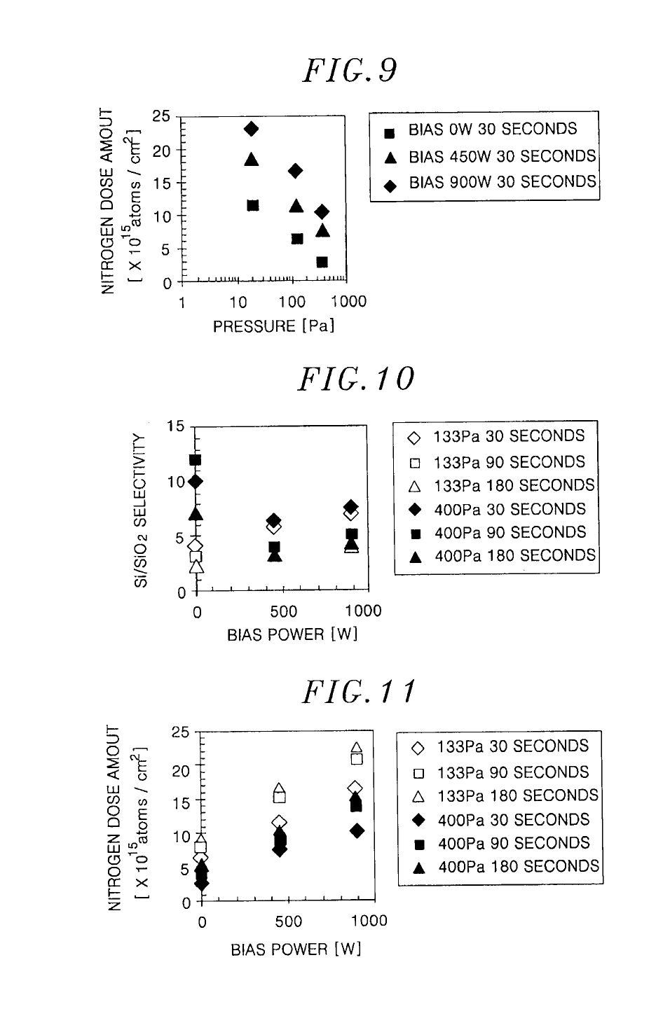

FIGS. 8 to 13 show more detailed data on a process pressure, a level of a bias applied to a wafer W, and processing time. FIG. 8 shows pressure dependence of a Si/SiO₂ selectivity in the case of setting a bias power to 0 W (no application), 450 W and 900 W. At this time, the processing time was set to about 30 seconds. Referring to FIG. 8, at the process pressure of about 20 Pa, a sufficient Si/SiO₂ selectivity was not obtained both when a bias was applied and when a bias was not applied. However, the Si/SiO₂ selectivity was considerably improved by setting the process pressure to a high level (133 Pa, 400 Pa). Meanwhile, FIG. 9 shows pressure dependence of a nitrogen dose amount (or nitriding rate) to silicon under the same conditions as those described in FIG. 8. Unlike the case described in FIG. 8, both when a bias was applied and when a bias was not applied, the nitrogen dose amount (or nitriding rate) was decreased as the process pressure was increased. However, when a bias is applied, the ions are attracted to the wafer W, and the nitrogen dose amount (or nitriding rate) is shifted in an increasing direction. Hence, a higher dose amount (or a nitriding rate) is obtained compared to when a bias is not applied.

FIG. 10 shows power dependence of a Si/SiO₂ selectivity in the case of setting a process pressure to about 133 Pa or 400 Pa. The processing time was set to about 30 seconds, 90 seconds, and 180 seconds. Referring to FIG. 10, it is seen that, at the pressure of about 133 Pa, the Si/SiO₂ selectivity is gradually improved by increasing the bias power from 0 W (no application) to about 450 W and then to about 900 W. Meanwhile, at the pressure of about 400 Pa, the Si/SiO₂ selectivity is highest when the bias power is 0 W (no application). The Si/SiO₂ selectivity is remarkably decreased when the bias power is about 450 W, and is improved when the bias power is about 900 W. From this result, it is expected that the Si/SiO₂ selectivity is improved by increasing the bias power. However, when the process pressure is set to a high level higher than about 400 Pa, the bias power is remarkably decreased by the bias application. Therefore, the process pressure needs to be set within the range in which the Si/SiO₂ selectivity is not decreased remarkably. FIG. 11 shows bias power dependence of a nitrogen dose amount (or a nitriding rate) to silicon under the same conditions as those described in FIG. 10. At the pressure of about 133 Pa and 400 Pa, the nitrogen dose amount (or nitriding rate) to silicon was gradually improved by increasing the bias power from 0 W (no application) to about 450 W and then to about 900 W.

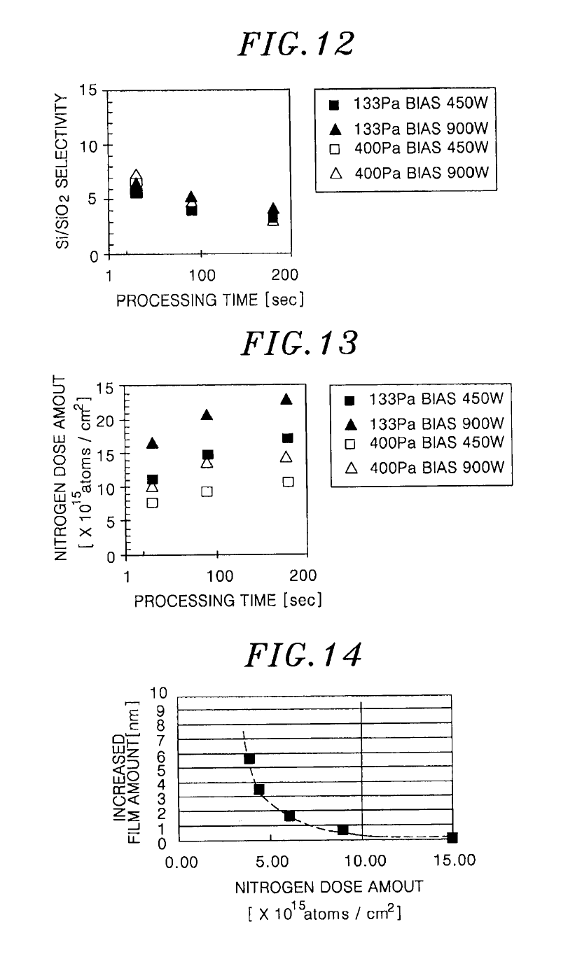

FIG. 12 shows processing time dependence of a Si/SiO₂ selectivity in the case of setting a process pressure to about 133 Pa or 400 Pa. The bias power was set to about 450 W and 900 W. Referring to FIG. 12, is seen that, at the pressure of about 133 Pa and 400 Pa, the Si/SiO₂ selectivity is decreased as the processing time is increased. Meanwhile, FIG. 13 shows processing time dependence of a nitrogen dose amount (or a nitriding rate) to silicon under the same conditions as those described in FIG. 12. Unlike the case described in FIG. 12, at the pressure of about 133 Pa and 400 Pa, the nitrogen dose amount (or nitriding rate) was increased as the processing time was increased.

In order to increase the Si/SiO₂ selectivity, the process pressure in the selective plasma nitriding process of the present invention is preferably set in the range of about 66.7 Pa to 667 Pa, and more preferably set in the range of about 66.7 Pa to 133 Pa. Further, the high frequency bias power is preferably set to be higher than or equal to about 100 W. For example, the high frequency bias power is preferably set in the range of about 100 W to 1500 W, and more preferably set in the range of about 300 W to 1000 W. The processing time may be set in accordance with other plasma processing conditions such as a thickness of a silicon nitriding film to be formed, a process pressure, a high frequency power and the like. For example, the processing time is preferably set in the range of, e.g., about 10 seconds to 180 seconds, and more preferably set in the range of about 10 seconds to 90 seconds.

Hereinafter, the range of the nitrogen dose amount to silicon will be described. FIG. 14 shows relationship between an increased film amount and a nitrogen dose amount in a SiO₂ film in the case of performing an oxidation process after forming a silicon nitride film by nitriding silicon. In FIG. 14, the vertical axis represents an increased amount of an optical film thickness, and the horizontal axis represents a nitrogen dose amount in a SiO₂ film having a thickness of about 6 nm. The effect of reducing the increased film amount in the oxidation process to be performed later can be obtained by nitriding silicon. However, when the nitrogen dose amount is lower than about 10×10¹⁵ atoms/cm², the effect of reducing the increased film amount is not sufficiently obtained, as can be seen from FIG. 14. Accordingly, the nitrogen dose amount needs to be higher than or equal to about 10×10¹⁵ atoms/cm² in order to obtain the barrier property of the increased film.

Referring back to FIG. 7 for the nitrogen dose amount, when the plasma nitriding process is performed at a pressure of about 133 Pa without applying a bias, the nitrogen dose amount higher than or equal to about 10×10¹⁵ atoms/cm² is obtained in the range in which the Si/SiO₂ selectivity is lower than about 2, as indicated by a dotted line in FIG. 7. From the above, it is clear that if the nitrogen dose amount higher than or equal to about 10×10¹⁵ atoms/cm² is obtained in the range in which the Si/SiO₂ selectivity is higher than or equal to, e.g., about 2, the effect of bias application (the improvement of the Si/SiO₂ selectivity and the increase of the nitrogen dose amount) is obtained. Therefore, in order to nitride Si while minimizing nitriding of the SiO₂ film, the Si/SiO₂ selectivity in the selective plasma nitriding method of the present invention is preferably set to be greater than or equal to about 2, and more preferably set to be greater than or equal to about 4. The upper limit of the Si/SiO₂ selectivity is lower than or equal to about 10.

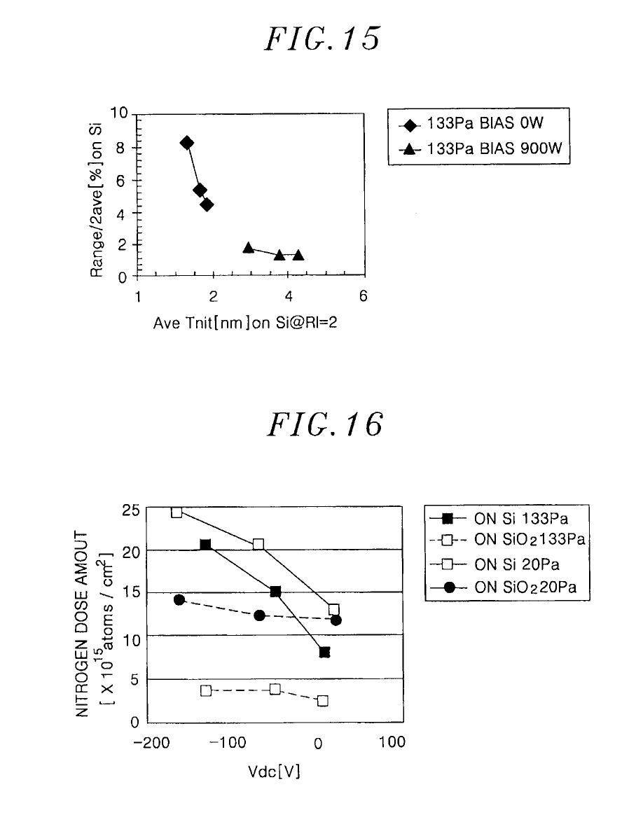

In the selective plasma nitriding process of the present invention, the uniformity of the nitriding process in the surface of the wafer W is improved by applying a bias to the wafer W. FIG. 15 shows measurement results of in-plane uniformity of a thickness of a silicon nitride film which are obtained when a bias is applied and when a bias is not applied under the pressure of 133 Pa. In FIG. 15, ┌Range/2ave[%]on Si┘ in the vertical axis represents a percentage of the silicon nitride film on silicon [(a maximum film thickness−a minimum film thickness)/an average film thickness×2], and ┌AVE Tnit[nm] on Si@RI=2] in the horizontal axis represents an average film thickness of the silicon nitride film. The number of measurement points on the wafer W is 49.

As can be seen from FIG. 15, the in-plane uniformity of the plasma nitriding process (i.e., the uniformity of the film thickness of the silicon nitride film in the surface of the wafer W) is considerably improved when a bias is applied, compared to when a bias is not applied. This is because, when a bias is applied, the attraction of ions is facilitated on the entire area of the mounting table 2 (wafer W), and the ions are sufficiently supplied to the entire surface of the wafer W even from a non-uniform plasma. Moreover, when a bias is applied, the nitriding rate and the film thickness of the silicon nitride film are increased, which results in the improvement of the uniformity.

Hereinafter, a mechanism of the selective plasma nitriding process of the present invention will be described with reference to FIG. 16. FIG. 16 shows relationship between a nitrogen dose amount and a Vdc in the case of performing a plasma nitriding process on a Si surface and a SiO₂ surface. Here, the Vdc in the horizontal axis represents an average potential of the wafer W mounted on the mounting table 2 in the case of applying a bias. Referring to the data of the nitriding of the SiO₂ surface which is indicated by the connected dotted lines in FIG. 16, the nitrogen dose amount measured at the process pressure of about 20 Pa and that measured at the process pressure of about 133 Pa have a large difference therebetween due to the pressure difference. However, at both pressure levels, the nitrogen dose amount to SiO₂ is not considerably increased even if the absolute value of Vdc is increased. The reason thereof is considered to be that a plasma in which radicals are predominant is generated at a pressure of about 133 Pa. Further, the effect of collision between ions and other particles is increased, so that the ion energy is not increased by the bias. On the other hand, the particle collision is suppressed at a pressure of about 20 Pa and, thus, the energy is increased by the bias application. However, the nitrogen dose amount to SiO₂ is not considerably increased. This is because, due to a plasma in which ions are predominant, a high nitrogen dose amount is already obtained at a level at which a bias is not applied (0 W). Therefore, the nitrogen dose amount is gradually increased even if the energy is increased.

Meanwhile, referring to the data of the nitriding of Si which is indicated by the connected solid lines in FIG. 16, the variation of the nitrogen dose amount by the change in Vdc is larger than the variation of the nitrogen dose amount by the pressure difference, and the effect of Vdc on the variation of the nitrogen dose amount is predominant. This is because, due to the low binding energy of Si—Si bonding, the nitrogen dose amount is affected more by the increase of the ion density by the bias application than by the ion energy. However, at a pressure of about 20 Pa at which a plasma in which ions are predominant is generated, the Si/SiO₂ selectivity is low due to the high nitriding rates of the Si surface and the SiO₂ surface. On the other hand, at a pressure of about 133 Pa at which a plasma in which radicals are predominant is generated, a high Si/SiO₂ selectivity can be obtained, and the nitrogen dose amount can be improved by the bias application. From the above result, it is clear that, by applying a bias at a pressure of about 133 Pa, it is possible to increase the ion density instead of the ion energy, and improve the nitrogen dose amount to Si and the nitriding rate without increasing the nitrogen dose amount to SiO₂.

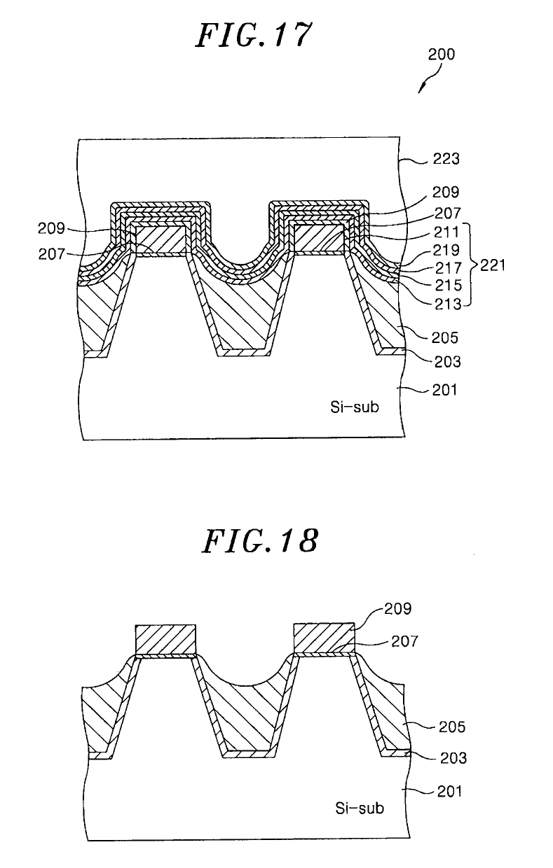

Hereinafter, in order to remarkably exhibit the effect of the present invention, the case in which the selective plasma nitriding process of the present invention is applied to a non-volatile memory manufacturing process will be described as an example. FIG. 17 is a cross sectional view showing a schematic configuration of a flash memory that can be fabricated by the method of the present invention. A flash memory 200 has a laminated structure in which an upper portion and a lower portion are nitrided to form ONO films (silicon oxide film—silicon nitride film—silicon oxide film) serving as an interlayer capacitive film between the floating gate electrode and the control gate electrode.

As shown in FIG. 17, a recess (trench) is formed on a silicon substrate 201 by, e.g., STI (Shallow Trench Isolation), and an isolation film 205 is formed therein via a liner silicon oxide film 203. A floating gate electrode 209 made of, e.g., polysilicon, is formed on the protrusion (between the recesses) of the silicon substrate 201 via a tunnel insulating film 207. The floating gate electrode 209 where electrons are accumulated is covered by an interlayer capacitance film 221 as a five-layer insulating film including a first silicon nitride film 211, a first silicon oxide film 213, a second silicon nitride film, a second silicon oxide film 217 and a third silicon nitride film 219 which are laminated from the bottom in that order. Further, a control gate electrode 223 made of, e.g., polysilicon, is formed on the interlayer capacitance film 221. In this manner, the flash memory 200 is fabricated.

The selective plasma nitriding method of the present invention can be applied to, e.g., the process for forming the first silicon nitride film 211. As clearly can be seen from FIG. 17, the first silicon nitride film 211 is formed so as to cover the surface of the floating gate electrode 209 except the surface of the isolation film 205. With this structure, in the flash memory 200, the interference between adjacent cells, specifically the movement of electrons, can be suppressed, and the good data retention characteristics can be achieved.

FIG. 18 shows a cross sectional structure of principal parts of the wafer W during the fabrication of the flash memory 200 as an object to be subjected to the selective plasma nitriding process of the present invention. The floating gate electrode 209 mainly made of polysilicon is formed on the silicon substrate 201 via the tunnel insulating film 207. The tunnel insulating film 207 and the floating gate electrode 209 can be formed by a well-known film forming process, photolithography technique and etching process. The liner silicon oxide film 203 is formed on an inner surface of the recess of the silicon substrate 201, and the isolation film 205 is buried therein via the liner silicon oxide film 203. The isolation film 205 defines an active region and a field region on the flash memory 200. The isolation film 205 is obtained by forming a silicon dioxide (SiO₂) film by using, e.g., a HDP-CVD (High Density Plasma Chemical Vapor Deposition) method or a SOG (Spin-On-Glass) method, and then performing wet etching using dilute hydrofluoric acid or the like and etch back treatment.

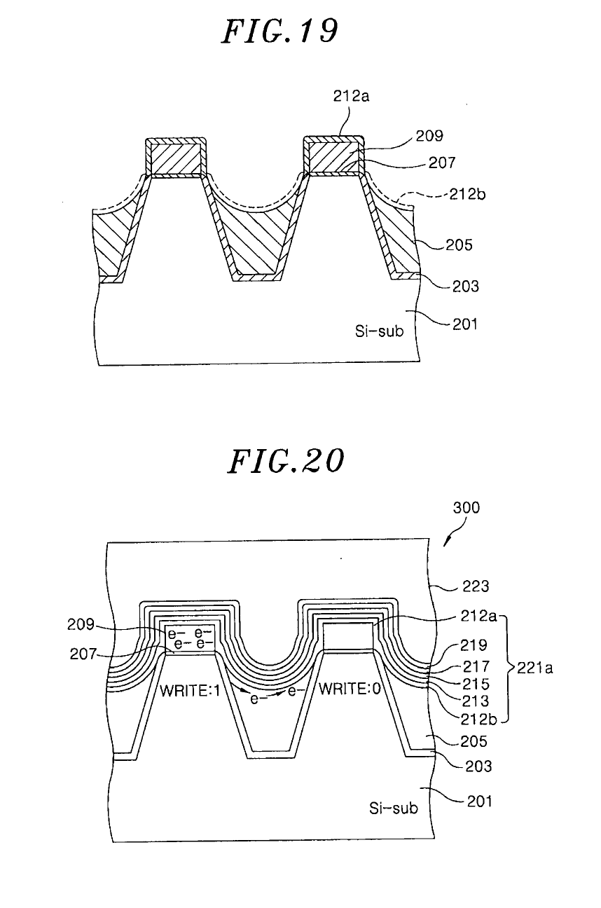

A selective plasma nitriding process is performed on polysilicon of the floating gate electrode 209 of the wafer W (the silicon substrate 201) having a state shown in FIG. 18. The selective plasma nitriding process can be performed under the aforementioned conditions. FIG. 19 shows a state in which nitrogen-containing layers 212a and 212b are formed by the selective plasma nitriding process. The nitrogen-containing layer 212a made of silicon nitride (SiN) is formed on the surface of the floating gate electrode 209 mainly made of polysilicon. Meanwhile, when the Si/SiO₂ selectivity is 1, the nitrogen-containing layer 212b made of silicon oxynitride (SiON) and having the same thickness as that of the nitrogen-containing layer 212a is formed on the surface of the isolation film 205 made of silicon dioxide (SiO₂), as indicated by dashed lines. However, the nitrogen-containing layer 212b is hardly formed by the selective plasma nitriding process. Moreover, the nitrogen-containing layer 212b made of silicon oxynitride (SiON) formed on the surface of the isolation film 205 can be easily removed by performing wet etching using, e.g., dilute hydrofluoric acid. The remaining nitrogen-containing layer 212a serves as the first silicon nitride film 211 forming a part of the interlayer capacitance film 221 in the flash memory 200 (see FIG. 17).

The processes following thereafter can be performed by a general method. That is, the first silicon oxide film 213, the second silicon nitride film 215, the second silicon oxide film 217 and the third silicon nitride film 219 are sequentially laminated on the first silicon nitride film 211, thereby forming the interlayer capacitance film 221. Thereafter, the control gate electrode 223 is formed on the third silicon nitride film 219 by a CVD method or the like. In this manner, the flash memory 200 having a structure shown in FIG. 17 can be fabricated.

Hereinafter, the advantages of the flash memory 200 fabricated by applying the method of the present invention to a part of the processes will be described in comparison with a flash memory fabricated by a conventional method. FIG. 20 schematically shows a structure of a flash memory 300 manufactured by the conventional method. In the flash memory 300, the nitrogen-containing layer 212B made of silicon oxynitride (SiON) is formed on the surface of the isolation film 205 by a (non-selective) plasma nitriding process while extending from the nitrogen-containing layer 212a (corresponding to the first silicon nitride film 211 in FIG. 17) formed on the surface of the floating gate electrode 209. In other words, an interlayer capacitance layer 221a is different from the flash memory 200 shown in FIG. 17 in that it includes the nitrogen-containing layer 212b. Further, in the flash memory 300 shown in FIG. 20, like reference numerals will be given to like parts having the same configurations as those of the flash memory 200 shown in FIG. 17, and redundant description thereof will be omitted.

The unnecessary nitrogen-containing layer 212b (the silicon oxynitride film) serving as an electron movement route causes interference between adjacent cells and deteriorates the data retention characteristics of the flash memory 300. In other words, when the write states of the adjacent cells of the flash memory 300 are different (i.e., when write is 0 or 1), electrons move from a cell in which charges are injected to the floating gate electrode 209 toward an adjacent cell in which charges are not injected to the floating gate electrode 200 via the nitrogen-containing layer 212b adjacent to the isolation film 205, thereby deteriorating the data retention characteristics. For example, between two cells separated by the isolation film 205 in FIG. 20, one cell (left side) in which electrons are injected to the floating gate electrode 209 is set to a write state (write; 1), and the other cell (right side) in which electrons are not injected to the floating gate electrode 209 is set to an erase state (write; 0). If this state is continued for a long period of time, the electrons flow from the cell in the write state toward the cell in the erase state via the nitrogen-containing layer 212b formed between the isolation film 205 and the first silicon oxide film 213, as indicated by arrows in FIG. 20. Hence, the threshold voltage of the cell in the write state (write; 1) changes, and the data retention characteristics deteriorate. Since the interlayer capacitance film 221a having a high barrier height is interposed between the floating gate electrode 209 and the control gate electrode 223, the electrons hardly leak in the direction of penetrating the interlayer capacitance film 221a. On the other hand, the nitrogen containing layer 212b which is formed by a non-selective plasma nitriding process and positioned adjacent to the floating gate electrode 209 has a relatively small energy band gap and a low barrier height, so that a small amount of electrons leak from the floating gate electrode 209 to the nitrogen containing layer 212b. Further, it is considered that the electrons move to the adjacent cell while being transferred through the defects in the nitrogen-containing layer 212b.

Meanwhile, in the flash memory 200 (FIG. 17) manufactured by the method of the present invention, the nitrogen-containing layer (‘212b’ in FIG. 19) is hardly formed on the isolation film 205 due to the selective plasma nitriding process. Even if the nitrogen-containing layer is formed, it can be easily removed by etching. Hence, the first silicon nitride film 211 is terminated around the floating gate electrode 209. Accordingly, the electrons do not move along the nitrogen-containing layer on the isolation film 205, and the interference between adjacent cells is prevented.

As described above, by applying the method of the present invention to the manufacturing process of the flash memory 200, it is possible to improve the reliability of the flash memory 200 and maintain the good data retention characteristics of the flash memory 200 while preventing the interference between adjacent cells.

While the embodiments of the invention have been described as examples in detail, the present invention is not limited to the above-described embodiments. It will be understood by those skilled in the art that various changes and modification may be made without departing from the scope of the invention, and such changes and modifications are considered to fall within the technical scope of the present invention. For example, in the above embodiment, the RLSA-type plasma nitriding apparatus 100 is used. However, another type plasma processing apparatus may also be used. For example, a plasma processing apparatus using an electron cyclotron resonance (ECR) plasma, a magnetron plasma, a surface wave plasma (SWP) or the like may be used.

Further, in the application example of the method of the present invention, the flash memory device 200 having a laminated structure in which an upper and a lower portion of the ONO films are nitrided is used as an example of the interlayer capacitance film 221. However, it is only an example, and the present invention can be applied to, e.g., fabrication of a flash memory having a structure in which NONO films are laminated from the bottom (the floating gate electrode side), or fabrication of a semiconductor device which has exposed surfaces of Si and SiO₂ and requires a selective nitriding process.

1. A method for selectively nitriding an object, the method comprising:
(I) mounting an object to be processed on a mounting table in a processing chamber of a plasma processing apparatus, the object comprising a silicon surface and a silicon compound layer exposed;
(II) setting a pressure in the processing chamber within a range of about 66.7 Pa to 667 Pa;
(III) generating a nitrogen-comprising plasma while applying a bias voltage to the object by supplying a high frequency power with an output of about 0.1 W/cm² to 1.2 W/cm² per unit area of the object to the mounting table; and
(IV) selectively nitriding the silicon surface with the nitrogen-comprising plasma, to form a silicon nitride film.

2. The method of claim 1, wherein the silicon compound layer is a silicon oxide film.

3. The method of claim 2, wherein a nitriding selectivity of the silicon to the silicon oxide film, (Si/SiO₂), is greater than or equal to 2.

4. The method of claim 1, wherein the pressure in the processing chamber is set within a range of about 133 Pa to 400 Pa.

5. The method of claim 1, wherein a frequency of the high frequency power is in a range of about 400 kHz to 60 MHz.

6. The method of claim 1, wherein a processing time is in a range of about 10 seconds to 180 seconds.

7. The method of claim 1, wherein a processing time is in a range of about 10 seconds to 90 seconds.

8. The method of claim 1, wherein the nitrogen-comprising plasma is a microwave excitation plasma generated by a processing gas and a microwave introduced into the processing chamber by a planar antenna comprising a plurality of slots.

9. The method of claim 8, wherein a power density of the microwave per unit area of the object is in a range of about 0.255 W/cm² to 2.55 W/cm².

10. The method of claim 1, wherein a process temperature is in a range of about 25° C. to 600° C.

11. A plasma nitriding apparatus, comprising:
a processing chamber, which processes an object comprising a silicon surface and a silicon compound layer exposed with a plasma;
a gas exhaust unit, which depressurizes and exhausts an interior of the processing chamber;
a plasma generation unit, which generates a plasma in the processing chamber;
a mounting table, to which the object in the processing chamber is mounted;
a high frequency power supply connected to the mounting table; and
a control unit, which is programmed to control a selective plasma processing method to be performed,
wherein the selective plasma processing method comprises:
(I) setting a pressure in the processing chamber within a range of about 66.7 Pa to 667 Pa;
(II) generating a nitrogen-comprising plasma while applying a bias voltage to the object to be processed by supplying a high frequency power with an output of about 0.1 W/cm² to 1.2 W/cm² per unit area of the object to the mounting table; and
(III) selectively nitriding the silicon surface by the nitrogen-comprising plasma, to form a silicon nitride film.

12. The method of claim 2, wherein a nitriding selectivity of the silicon to the silicon oxide film, (Si/SiO₂), is greater than or equal to 4.

13. The method of claim 1, the high frequency power output is in a range from about 0.4 W/cm² to 1.2 W/cm² per unit area of the object.

14. The method of claim 1, wherein a frequency of the high frequency power is in a range of about 400 kHz to 13.5 MHz.

15. The method of claim 1, wherein a process temperature is in a range of about 200° C. to 500° C.

16. The method of claim 1, wherein a process temperature is in a range of about 400° C. to 500° C.
